(19) United States
(12) Patent Application Publication
(10) Pub. No.: US 2003/0031063 A1
(43) Pub. Date: Feb. 13, 2003

(54) Semiconductor integrated circuit and electronic apparatus including the same

(75) Inventors: Nobumitsu Amachi, Kusatsu-shi (JP); Hiroki Fujiwara, Omihachiman-shi (JP)

Correspondence Address: Keating & Bennett LLP, 10400 Eaton Place, Suite 312, Fairfax, VA, 22030, US

(73) Assignee: Murata Manufacturing Co., Ltd., Nagaokakyo-shi (JP)

(21) Appl. No.: 10/187,988

(22) Filed: Jul. 3, 2002

(30) Foreign Application Priority Data
Aug. 9, 2001 (JP) 2001-242411

(51) Int. Cl. G11C 7/00; G11C 29/00

(52) U.S. Cl. 365/200

(57) ABSTRACT

A semiconductor integrated circuit prevents the circuit elements thereof from being destroyed by a surge current flowing therethrough when the semiconductor integrated circuit is electrically charged and improves the electrostatic tolerance thereof.

### BACKGROUND OF THE INVENTION

1. Field of the Invention

The present invention relates to a semiconductor integrated circuit and an electronic apparatus including such a semiconductor integrated circuit, and particularly relates to a semiconductor integrated circuit that achieves a high electrostatic tolerance and an electronic apparatus including such a semiconductor integrated circuit.

2. Description of the Related Art

FIG. 6 shows the circuit diagram of a related semiconductor integrated circuit 1 (hereinafter referred to as the circuit 1). As shown in the drawing, the circuit 1 is an RF small-power amplifying circuit, including an FET Q1 defining an active element, resistors R1, R2, and R3, capacitors C1, C2, and C3, and diodes D1, D2, and D3 functioning as surge-absorbing elements disposed on a semiconductor substrate. The circuit 1 further includes external terminals T1, T2, and T3.

The semiconductor substrate is a chemical compound semiconductor substrate or a GaAs substrate. The FET Q1 is a metal-semiconductor FET (MESFET) having a gate that is 300 μm in width and 0.5 μm in length, and is disposed on the GaAs substrate. The electrostatic tolerance of the FET Q1 is relatively low. The capacitors C1 to C3 are so-called metal insulator metal (MIM) capacitors, each including a silicon nitride film having a thickness of 0.2 nm between metal layers. The electrostatic tolerances of the capacitors C1 to C3 are low. The capacitance of the capacitors C1 and C2 is 3 pF, and the capacitance of the capacitor C3 is 5 pF. The resistors are formed at the predetermined positions on the GaAs substrate by using ion implantation. The resistance of the resistor R1 is 5 kΩ, the resistance of the resistor R2 is 200 Ω, and the resistance of the resistor R3 is 40 Ω. Each of the diodes D1 to D3 includes two diodes, each of which includes a cathode. The cathodes are connected to each other, whereby a so-called back-to-back diode (BBD) is provided.

The gate of the FET Q1 is grounded via the resistor R1 and is connected to the external terminal T1 via the capacitor C1. The drain of the FET Q1 is connected to the external terminal T2 via the resistor R2 and is connected to the external terminal T3 via the capacitor C2. The source of the FET Q1 is grounded via the resistor R3 and the capacitor C3, which are connected in parallel. One end of the capacitor C1, which is directly connected to the external terminal T1, is grounded via the diode D1. One end of the resistor R2, which is directly connected to the external terminal T2, is grounded via the diode D2. One end of the capacitor C2, which is directly connected to the external terminal T3, is grounded via the diode D3.

When a surge voltage is applied to the external terminal T1, it is absorbed by the diode D1 and flows to ground. Therefore, the capacitor C1 and the gate of the FET Q1 are prevented from being destroyed by the high voltage. When another surge voltage is applied to the external terminal T2, it is absorbed by the diode D2 and flows to ground. Therefore, the capacitor C2 and the drain of the FET Q1 are prevented from being destroyed by the high voltage. When another surge voltage is applied to the external terminal T3, it is absorbed by the diode D3 and is refluxed to ground. Therefore, the capacitor C2 and the drain of the FET Q1 are prevented from being destroyed by the high voltage.

According to the configuration of the circuit 1, the diodes D1 to D3 functioning as surge-absorbing elements are connected to the terminal ends of the circuit elements, the terminal ends being connected to the external terminals. Therefore, the circuit elements are prevented from being destroyed by the high voltages or the surge voltages.

Sometimes, general semiconductor integrated circuits are electrically charged when tape used for mounting is torn off. When the circuit 1 is electrically charged due to such a reason, it is impossible to prevent the circuit elements thereof from being destroyed.

A case wherein the circuit 1 is electrically charged and the external terminal T1 comes into contact with an external metal on which the circuit elements are grounded will now be considered. In such a case, an electric charge that is accumulated in the circuit 1 is discharged to the external terminal T1 via the capacitor C3, the FET Q1, and the capacitor C1. Subsequently, these three circuit elements are destroyed. When the external terminal T2 comes into contact with an external metal on which the circuit elements are grounded, the electric charge accumulated in the circuit 1 is discharged to the external terminal T2 via the capacitor C3, the FET Q1, and the resistor R2. Subsequently, the capacitor C3 and the FET Q1 are destroyed. Since the resistor R2 has a high surge resistance, it is not destroyed by normal static electricity. When the external terminal T3 comes into contact with an external metal on which the circuit elements are grounded, electric charge accumulated in the circuit 1 is discharged to the external terminal T3 via the capacitor C3, the FET Q1, and the capacitor C2. Subsequently, these three circuit elements are destroyed.

According to the configuration of the circuit 1, the surge-absorbing elements are connected to the terminal ends of the circuit elements, the terminal ends being directly connected to the external terminals. In such case, however, it is impossible to prevent the circuit elements from being destroyed.

### SUMMARY OF THE INVENTION

In order to overcome the problems described above, preferred embodiments of the present invention provide a semiconductor integrated circuit that prevents the circuit elements thereof from being destroyed when the semiconductor integrated circuit is electrically charged, and an electronic apparatus including such a novel semiconductor integrated circuit.

According to a preferred embodiment of the present invention, a semiconductor integrated circuit includes a substrate, an external terminal disposed on the substrate, at least one circuit element disposed on the substrate, the circuit element having a terminal end that is not directly connected to the external terminal, and a surge-absorbing element disposed on the substrate, which is connected to the terminal end.

In one preferred embodiment of the present invention, the circuit element of the semiconductor integrated circuit is an FET.

In another preferred embodiment of the present invention, the circuit element of the semiconductor integrated circuit is a capacitor.

In a preferred embodiment of the present invention, the surge-absorbing element of the semiconductor integrated circuit includes at least one diode.

In another preferred embodiment of the present invention, the surge-absorbing element of the semiconductor integrated circuit includes two diodes connected in series in opposite directions.

In a further preferred embodiment of the present invention, the substrate of the semiconductor integrated circuit is a chemical compound semiconductor substrate.

According to another preferred embodiment of the present invention, an electronic apparatus includes a semiconductor integrated circuit according to preferred embodiments described above.

According to the above-described configuration, the circuit elements of the semiconductor integrated circuit are prevented from being destroyed when the semiconductor integrated circuit is electrically charged. Subsequently, the yield of the semiconductor integrated circuit is greatly improved and the cost thereof is decreased.

The cost of the electronic apparatus is reduced due to the increased yield of the semiconductor integrated circuit. However, since electrostatic discharge, which occurs when the electronic apparatus is assembled, is eliminated and the yield of the electronic apparatus is increased, the cost is further reduced and a high electrostatic tolerance is achieved.

Other features, elements, characteristics and advantages of the present invention will become more apparent from the following detailed description of preferred embodiments thereof with reference to the attached drawings.

### BRIEF DESCRIPTION OF THE DRAWINGS

FIG. 1 is a circuit diagram of a semiconductor integrated circuit according to a preferred embodiment of the present invention;

FIG. 2 is a circuit diagram of a semiconductor integrated circuit according to another preferred embodiment of the present invention;

FIG. 3 is a circuit diagram of a semiconductor integrated circuit according to another preferred embodiment of the present invention;

FIG. 4 is a circuit diagram of a semiconductor integrated circuit according to another preferred embodiment of the present invention;

FIG. 5 is a perspective view of an electronic apparatus according to another preferred embodiment of the present invention; and

FIG. 6 is a circuit diagram of a related semiconductor integrated circuit.

### DESCRIPTION DETAILED OF PREFERRED EMBODIMENTS

FIG. 1 shows the circuit diagram of a semiconductor integrated circuit 5 (hereinafter referred to as the circuit 5) according to a preferred embodiment of the present invention. In this drawing, like elements or the same elements as in FIG. 6 are designated by the same reference characters and reference numerals, and the explanation thereof is omitted.

The configuration of the circuit 5 will now be described. The circuit 5 preferably includes a field effect transistor (FET) Q1, diodes D1 to D5, resistors R1 to R3, capacitors C1 to C3, and terminals T1 to T3. The gate of the FET Q1, which is a terminal that is not directly connected to an external terminal, is grounded via the diode D4. The source of the FET Q1, which is another terminal that is not directly connected to the external terminal, is grounded via the diode DS, which functions as a surge-absorbing element. That is to say, the diode D4 is connected to the terminal of the FET Q1 that is a circuit element having a low electrostatic tolerance. The diode D5 is connected to the FET Q1 and to the terminal of the capacitor C3. The diodes D4 and D5 are BBDS, as are the diodes D1, D2, and D3. Except for these diodes D4 and D5, the configuration of the circuit 5 is the same as the circuit 1 shown in FIG. 6, including the material and the circuit values. However, considering the importance of static protection, no surge-absorbing element is connected to the drain of the FET Q1, which is another terminal that is not directly connected to the external terminal. Thus, the surge-absorbing elements or the diodes D4 and D5 are respectively connected to the gate and the source of the FET Q1.

According to the above-described configuration, circuit elements of the circuit 5 are prevented from being destroyed by surge voltages applied to the external terminals, or by electrostatic charging of the circuit 5, as in the case of the related circuit 1. Such effects will be described below.

For example, a case wherein the circuit 5 is electrically charged, and the external terminal T1 comes into contact with the external metal on which the circuit elements are grounded will now be considered. In such a case, electric charges that are accumulated on the ground of the circuit 5 are mainly transmitted to the external terminal T1 via the diode D1. Incidentally, the word “mainly” is used because there are other current paths in the actual circuit. It should be noted that the word “mainly” will be omitted in the description of the current paths that follows. Electric charges that are accumulated on the external terminals T2 and T3 are transmitted to the external terminal T1 via the diode D2, the diode D3, and the diode D1. Electric charges that are accumulated on the source of the FET Q1 are transmitted to the external terminal T1 via the diode D5 and the diode D1. Electric charges that are accumulated on the drain of the FET Q1 are transmitted to the external terminal T1 via the portion between the drain and the source that are conductive, the diode D5, and the diode D1. Electric charges that are accumulated on the gate of the FET Q1 are transmitted to the external terminal T1 via the diode D4 and the diode D1. Thus, a surge current does not flow through the capacitor C3, the FET Q1, and the capacitor C1, and these three circuit elements are prevented from being destroyed.

Another case wherein the circuit 5 is electrically charged, and the external terminal T2 comes into contact with the external metal on which the circuit elements are grounded will now be considered. In such a case, electric charges that are accumulated on the ground of the circuit 5 are transmitted to the external terminal T2 via the diode D2. Electric charges accumulated on the external terminals T1 and T3 are transmitted to the external terminal T2 via the diode D1, the diode D3, and the diode D2. Electric charges that are accumulated on the source of the FET Q1 are transmitted to the external terminal T2 via the diode D5 and the diode D2. Electric charges that are accumulated on the drain of the FET Q1 are transmitted to the external terminal T2 via the portion between the drain and the source that are conductive, the diode D5, and the diode D2. Electric charges that are accumulated on the gate of the FET Q1 are transmitted to the external terminal T2 via the diode D4 and the diode D2. Thus, a surge current does not flow through the capacitor C3, the FET Q1, and the capacitor C1, and these three circuit elements are prevented from being destroyed.

Another case wherein the circuit 5 is electrically charged, and the external terminal T3 comes into contact with the external metal on which the circuit elements are grounded will now be considered. In such a case, electric charges that are accumulated on the ground of the circuit 5 are transmitted to the external terminal T3 via the diode D3. Electric charges that are accumulated on the external terminals T1 and T2 are transmitted to the external terminal T3 via the diode D1, the diode D2, and the diode D3. Electric charges that are accumulated on the source of the FET Q1 are transmitted to the external terminal T3 via the diode D5 and the diode D3. Electric charges that are accumulated on the drain of the FET Q1 are transmitted to the external terminal T3 via the portion between the drain and the source that are conductive, the diode D5, and the diode D3. Electric charges that are accumulated on the gate of the FET Q1 are transmitted to the external terminal T3 via the diode D4 and the diode D3. Thus, a surge current does not flow through the capacitor C3, the FET Q1, and the capacitor C1, and these three circuit elements are prevented from being destroyed.

Thus, by including the diodes D4 and D5, the circuit 5 can prevent the circuit elements having low electrostatic tolerances such as the FET Q1 and the capacitors C1 to C3 from being destroyed by a surge current flowing through the circuit 5 that is electrically charged. Accordingly, the electrostatic tolerance of the circuit 5 is increased.

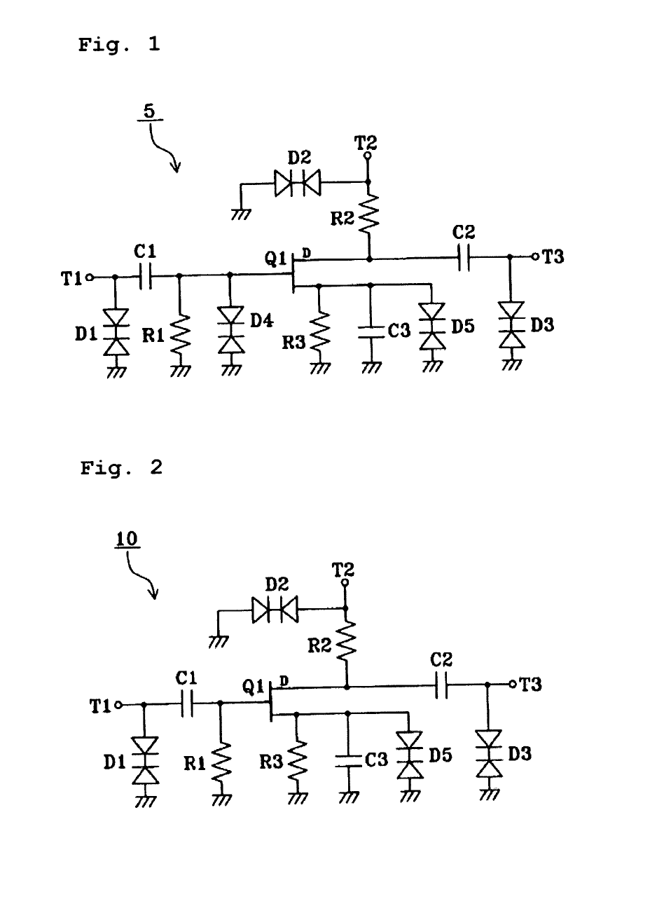

FIG. 2 shows the circuit diagram of a semiconductor integrated circuit 10 (hereinafter referred to as the circuit 10) according to another preferred embodiment of the present invention. In this drawing, like elements or the same elements as in the case shown in FIG. 1 are designated by the same reference characters and numerals, and the explanation thereof is omitted.

The configuration of the circuit 10 is basically the same as that of the circuit 5 shown in FIG. 1, except that the diode D4 is eliminated. This is because the diode D4, which is the surge-absorbing element, may cause deterioration in the radio-frequency characteristics of the circuit 10 when the diode D4 is connected to the gate of the FET Q1, which is a path through which radio-frequency signals are transmitted.

According to the above-described configuration, circuit elements of the circuit 10 are prevented from being destroyed by a surge voltage applied to the external terminals, or by electrostatic charging of the circuit 10. Such effects, which are the same as those of the circuit 5 shown in FIG. 1, will be omitted except the point referring to electric discharge from the gate of the FET Q1.

A case wherein the circuit 10 is electrically charged, and the external terminal T1 comes into contact with an external metal on which the circuit elements are grounded will now be considered. When electric charges that are accumulated on the gate of the FET Q1 are positive, the electric charges are transmitted to the external terminal T1 via the portion between the gate and the source of the FET Q1 acting as a forward-direction diode, the diode D5, and the diode D1. On the other hand, when electric charges that are accumulated on the gate of the FET Q1 are negative, the portion between the gate and the source of the FET Q1 becomes an inverse-direction diode. Since the diodes D5 and D1 acting as paths for the electrical discharge include the same inverse-direction diodes, the voltage applied between the gate and the source of the FET Q1 becomes as much as about one-third of the voltage applied between the gate of the FET Q1 and the external terminal T1. However, when the diode D5 is eliminated as in the case of the related circuit 1, the voltage applied between the gate and the source of the FET Q1 becomes as much as about one-half of the voltage applied between the gate of the FET Q1 and the external terminal T1, since there are only two inverse-direction diodes between the gate and the external terminal T1. Thus, the diode D5 allows for the voltage applied between the gate and the source of the FET Q1 to be decreased, thereby substantially increasing the peak inverse voltage. Accordingly, a surge current does not flow through the capacitor C3, the FET Q1, and the capacitor C1, and the possibility that these three circuit elements are destroyed is minimized.

Another case wherein the circuit 10 is electrically charged, and the external terminal T2 comes into contact with an external metal on which the circuit elements are grounded will now be considered. When electric charges that are accumulated on the gate of the FET Q1 are positive, the electric charges are transmitted to the external terminal T2 via a portion between the gate and the source of the FET Q1 acting as a forward-direction diode, the diode D5, and the diode D2. On the other hand, when electric charges that are accumulated on the gate of the FET Q1 are negative, the substantial withstand voltage between the source and the gate of the FET Q1 is increased as in the case where the external terminal T1 comes into contact with the external metal on which the external terminal T1 is grounded. Accordingly, a surge current does not flow through the capacitor C3, the FET Q1, and the capacitor C1, and the possibility that these three circuit elements are destroyed is reduced.

Another case wherein the circuit 10 is electrically charged, and the external terminal T3 comes into contact with an external metal on which the external terminal T3 is grounded will now be considered. When electric charges that are accumulated on the gate of the FET Q1 are positive, the electric charges are transmitted to the external terminal T3 via the portion between the gate and the source of the FET Q1 acting as a forward-direction diode, the diode D5, and the diode D3. On the other hand, when electric charges that are accumulated on the gate of the FET Q1 are negative, the substantial withstand voltage between the source and the gate of the FET Q1 is increased as in the case where the external terminal T1 comes into contact with the external metal on which the external terminal T1 is grounded. Accordingly, a surge current does not flow through the capacitor C3, the FET Q1, and the capacitor C1, and the possibility that these three circuit elements are destroyed is reduced.

Thus, when the circuit 10 is electrically charged and the diode D4 is eliminated, the circuit 10 prevents the circuit elements having low electrostatic tolerances such as the FET Q1 and the capacitors C1 to C3 from being destroyed by a surge current flowing through the circuit 10. Accordingly, the electrostatic tolerance of the circuit 10 is increased.

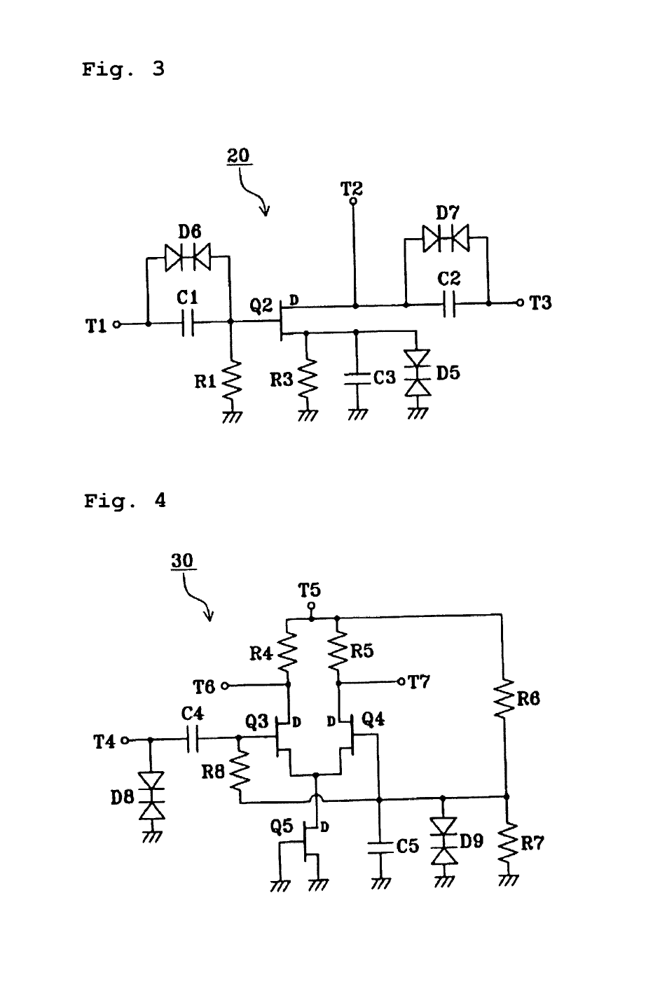

FIG. 3 shows the circuit diagram of a semiconductor integrated circuit 20 (hereinafter referred to as the circuit 20) according to another preferred embodiment of the present invention. In this drawing, like elements and the same elements as in FIG. 2 are designated by the same reference numerals and reference characters, and the explanation thereof is omitted.

The circuit 20 includes an FET Q2, which preferably is a MESFET that defines an active element, in place of the FET Q1. The resistor R2 and the diodes D1 to D3 are eliminated, but a diode D6 and a diode D7 are connected in parallel to the capacitor C1 and the capacitor C2, respectively. The gate width of the FET Q2 is about 2 mm and the gate length thereof is about 0.8 μm. The electrostatic tolerance of the FET Q2 is higher than that of the FET Q1. Thus, the circuit 20 is configured as an RF large-power amplifying circuit. The diodes D6 and D7 are BBDs, like the diode D5. Except for these diodes D6 and D7, the configuration of the circuit 20 is the same as the circuit 10, including the material and the circuit values.

The above-described circuit 20 can prevent the circuit elements from being destroyed by a surge voltage applied to the external terminals, and by electrostatic charging of the circuit 20 as in the case of the related circuit 1. These effects will now be described below.

First, a case wherein a surge voltage is applied to the external terminal T1 will be considered. The surge voltage is applied to the gate of the FET Q2 via the diode D6. The capacitor C1 is not destroyed, since the surge voltage is not applied to it. The surge voltage applied to the gate of the FET Q2 flows to ground via the portion between the gate and the source of the FET Q2 and the diode D5. At this time, the FET Q2 is not destroyed due to the high electrostatic tolerance. Since the surge voltage is not applied, the capacitor C3 is not destroyed.

Another case wherein a surge voltage is applied to the external terminal T2 will be considered. The surge voltage applied to the external terminal T2 flows to ground via the portion between the drain and the source of the FET Q2, which are conductive, and via the diode D5. The FET Q2 having the high electrostatic tolerance and the capacitor C3 to which the surge voltage is not applied are not destroyed.

Another case wherein a surge voltage is applied to the external terminal T3 will be considered. The surge voltage is applied to the drain of the FET Q2 via the diode D7. Since the surge voltage is not applied to the capacitor C2, the capacitor C2 is not destroyed. The surge voltage applied to the drain of the FET Q2 flows to ground via the portion between the drain and the source that are conductive, and via the diode D5. The FET Q2 having the high electrostatic tolerance and the capacitor C3 to which the surge voltage is not applied are not destroyed.

Another case wherein the circuit 20 is electrically charged, and the external terminal T1 comes into contact with an external metal on which the circuit elements are grounded will now be considered. In this case, electric charges that are accumulated on the ground of the circuit 20 are transmitted to the external terminal T1 via the diode D5, the portion between the source and the gate of the FET Q2, and the diode D6. The FET Q2 having the high electrostatic tolerance and the capacitors C1 and C3 to which the surge voltage is not applied are not destroyed. Electric charges that are accumulated on the external terminal T2 are transmitted to the external terminal T1 via the portion between the drain and the gate of the FET Q2, and the diode D6. The FET Q2 having the high electrostatic tolerance and the capacitor C1 to which the surge voltage is not applied are not destroyed. Electric charges that are accumulated on the external terminal T3 are transmitted to the external terminal T1 via the diode D7, the portion between the drain and the gate of the FET Q2, and the diode D6. The FET Q2 having the high electrostatic tolerance and the capacitors C1 and C2 to which the surge voltage is not applied are not destroyed. Electric charges that are accumulated on the gate of the FET Q2 are transmitted to the external terminal T1 via the diode D6. The FET Q2 having the high electrostatic tolerance and the capacitor C1 to which the surge voltage is not applied are not destroyed.

Another case wherein the circuit 20 is electrically charged, and the external terminal T2 comes into contact with an external metal on which the circuit elements are grounded will now be considered. In this case, electric charges that are accumulated on the ground of the circuit 20 are transmitted to the external terminal T2 via the diode D5 and the portion between the source and the drain of the FET Q2. The FET Q2 having the high electrostatic tolerance and the capacitor C3 to which the surge voltage is not applied are not destroyed. Electric charges that are accumulated on the external terminal T1 are transmitted to the external terminal T2 via the diode D6 and the portion between the gate and the drain of the FET Q2. The FET Q2 having the high electrostatic tolerance and the capacitor C1 to which the surge voltage is not applied are not destroyed. Electric charges that are accumulated on the external terminal T3 are transmitted to the external terminal T2 via the diode D7. The capacitor C2 to which the surge voltage is not applied is not destroyed. Electric charges that are accumulated on the gate of the FET Q2 are transmitted to the external terminal T2 via the portion between the gate and the drain of the FET Q2. The FET Q2, which has the high electrostatic tolerance, is not destroyed. Electric charges that are accumulated on the source of the FET Q2 are transmitted to the external terminal T2 via the portion between the source and the drain of the FET Q2. The FET Q2, which has the high electrostatic tolerance, is not destroyed.

Another case wherein the circuit 20 is electrically charged, and the external terminal T3 comes into contact with an external metal on which the circuit elements are grounded will now be considered. In this case, electric charges that are accumulated on the ground of the circuit 20 are transmitted to the external terminal T3 via the diode 5, the portion between the source and the drain of the FET Q2, and the diode D7. The FET Q2 having the high electrostatic tolerance and the capacitors C2 and C3, to which the surge voltage is not applied, are not destroyed. Electric charges that are accumulated on the external terminal T1 are transmitted to the external terminal T3 via the diode D6, the portion between the gate and the drain of the FET Q2, and the diode D7. The FET Q2, which has the high electrostatic tolerance, and the capacitors C1 and C2 to which the surge voltage is not applied are not destroyed. Electric charges that are accumulated on the external terminal T2 is transmitted to the external terminal T3 via the diode D7. The capacitor C2 to which the surge voltage is not applied is not destroyed. Electric charges that are accumulated on the gate of the FET Q2 are transmitted to the external terminal T3 via the portion between the gate and the drain of the FET Q2, and the diode D7. The FET Q2 having the high electrostatic tolerance and the capacitor C2 to which the surge voltage is not applied are not destroyed. Electric charges that are accumulated on the source of the FET Q2 are transmitted to the external terminal T3 via the portion between the source and the drain of the FET Q2 and the diode D7. The FET Q2, which has the high electrostatic tolerance, and the capacitor C2 to which the surge voltage is not applied are not destroyed.

Thus, when the circuit 20 is electrically charged and includes the diode D5 in addition to the diodes D6 and D7, the circuit 20 prevents the circuit elements having low electrostatic tolerances from being destroyed by the surge current flowing therethrough. Accordingly, the electrostatic tolerance of the circuit 20 is increased.

FIG. 4 shows the circuit diagram of a semiconductor integrated circuit 30 (hereinafter referred to as the circuit 30) according to another preferred embodiment of the present invention. As shown in the drawing, the circuit 30, which is configured as an RF small-power wideband differential amplifying circuit, preferably includes circuit elements such as active elements including FETs Q3, Q4, and Q5, and resistors R4, R5, R6, R7, and R8, and surge-absorbing elements including diodes D8 and D9 disposed on one semiconductor substrate preferably made of GaAs. The circuit 30 further includes external terminals T4, T5, T6, and T7.

Each of the FETs Q3, Q4, and Q5 is preferably a MESFET having a relatively low electrostatic tolerance as the FET Q1 of the related circuit 1. The capacitors C4 and C5 are so-called MIM capacitors and are formed at predetermined positions on the GaAs substrate preferably by using ion implantation. The diodes D8 and D9 are preferably BBDs.

The gate of the FET Q3 is connected to the external terminal T4 via the capacitor C4, and the drain is connected to the external terminal T5 via the resistor R4 and to the external terminal T6. The source is connected to the drain of the FET Q5. The gate of the FET Q4 is grounded via the capacitor C5, and the drain is connected to the external terminal T5 via the resistor R5, and to the external terminal T7. The source is connected to the drain of the FET Q5. Both the gate and the source of the FET Q5 are grounded. The external terminal T5 is grounded via the resistor R6 and the resistor R7 in that order, and the connection point therebetween is connected to the gate of the FET Q4 and, via the resistor R8, to the gate of the FET Q3. Since the capacitor C5 has a large capacitance, the gate of the FET Q4 can be RF grounded. One terminal end of the capacitor C4, which is directly connected to the external terminal T4, is grounded via the diode D8. First terminal ends of the FET Q4, the resistors R6, R7, and R8, and the capacitor C5, which are not directly connected to any of the external terminals, are grounded via the diode D9. That is to say, the diode D9 is connected to the terminal end of the FET Q4, which is a circuit element having a low electrostatic tolerance, and to the terminal end of the capacitor C5. Some terminal ends of the circuit elements are directly connected to the external terminals T5, T6, and T7. Surge-absorbing elements can be connected to such terminal ends. However, the importance of static protection for such terminals ends is low. Therefore, surge-absorbing elements are not connected to such terminal ends in this preferred embodiment. There are many other terminal ends that are not directly connected to the external terminals. However, considering the importance of static protection and the deterioration of the radio-frequency characteristic caused by connecting the terminal ends to the path through which radio-frequency signals flow, only the diode D9, which functions as a surge-absorbing element, is connected to the terminal ends that are not directly connected to the external terminals.

Accordingly, a surge voltage applied to the external terminal T4 is absorbed by the diode D8 and flows to ground. Therefore, the capacitor C5 and the gate of the FET Q3 are prevented from being destroyed by high voltages. The explanation of a case wherein a surge voltage is applied to the external terminals T5, T6, and T7 is omitted.

Further, when the circuit 30 is electrically charged and any of the external terminals comes into contact with an external metal on which the circuit elements are grounded, a surge voltage, which may flow through the capacitor C5 having the lowest electrostatic tolerance, flows via the diode D9. Thus, the capacitor C5 is prevented from being destroyed.

Thus, by including the diode D9 in addition to the diode D8, the circuit 30 prevents the circuit elements having low electrostatic tolerances from being destroyed by a surge current flowing therethrough. Accordingly, the electrostatic tolerance of the circuit 30 is increased.

In the above-described preferred embodiments, so-called BBDs are used as the surge-absorbing elements. However, the same effect can be expected in a case wherein the surge-absorbing elements include a single diode or a transistor, or a resistor having a small value, a silicon substrate is used as the circuit substrate, and the circuit elements include a CMOSFET, a bipolar transistor, a SiGe transistor, a JFET, a HEMT, or a HJFET, which has low electrostatic tolerances.

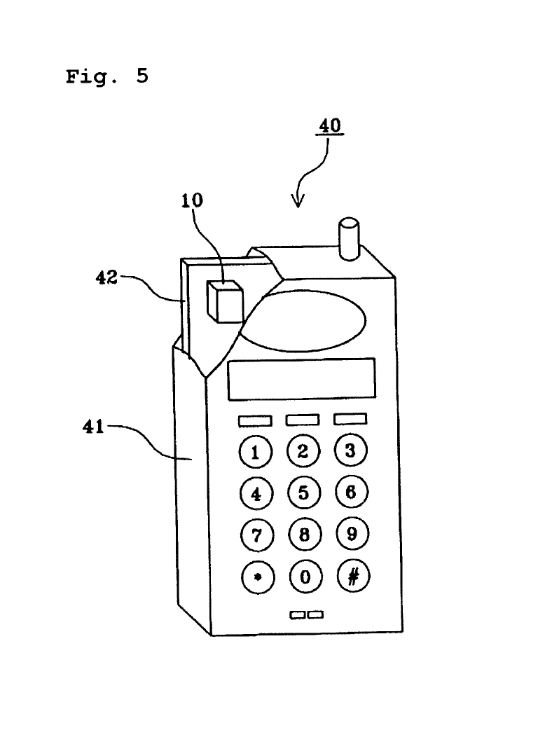

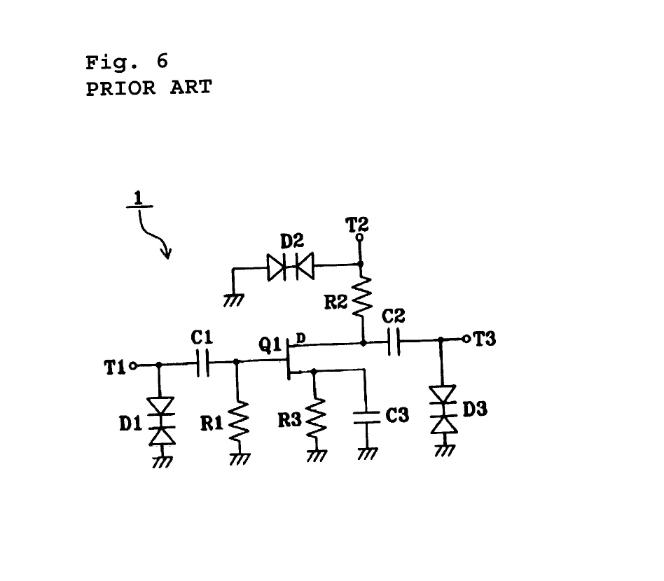

FIG. 5 shows the perspective view of an electronic apparatus according to another preferred embodiment of the present invention. As shown in this drawing, a mobile phone 40, which is an exemplary electronic apparatus, includes a cabinet 41, a printed board 42, and the circuit 10 mounted on the printed board 42.

Since the mobile phone 40 includes the circuit 10 according to other preferred embodiments of the present invention, the cost thereof is reduced, and the electrostatic tolerance thereof becomes high.

In this drawing, the mobile phone 40 is shown as the exemplary electronic apparatus. However, the use of the semiconductor integrated circuit of preferred embodiments of the present invention is not limited to mobile phones. The circuit can be used for any electronic apparatuses.

While preferred embodiments of the invention have been described above, it is to be understood that variations and modifications will be apparent to those skilled in the art without departing the scope and spirit of the invention. The scope of the invention, therefore, is to be determined solely by the following claims.

What is claimed is:

1. A semiconductor integrated circuit comprising:
a substrate;
an external terminal disposed on the substrate;
at least one circuit element disposed on the substrate, the at least one circuit element having a terminal end that is not directly connected to the external terminal; and
a surge-absorbing element disposed on the substrate, the surge-absorbing element being connected to the terminal end.

2. A semiconductor integrated circuit according to claim 1, wherein the circuit element is an FET.

3. A semiconductor integrated circuit according to claim 1, wherein the circuit element is a capacitor.

4. A semiconductor integrated circuit according to claim 1, wherein the surge-absorbing element includes at least one diode.

5. A semiconductor integrated circuit according to claim 1, wherein the surge-absorbing element includes two diodes connected in series in opposite directions.

6. A semiconductor integrated circuit according to claim 1, wherein the substrate is a chemical compound semiconductor substrate.

7. A semiconductor integrated circuit according to claim 1, further comprising additional circuit elements disposed on the substrate including a field effect transistor, a plurality of diodes, a plurality of resistors, a plurality of capacitors and a plurality of terminals.

8. A semiconductor integrated circuit according to claim 7, wherein the field effect transistor includes a gate and the gate is the terminal that is not directly connected to the external terminal.

9. A semiconductor integrated circuit according to claim 8, wherein the surge-absorbing element is connected to the gate of the field effect transistor.

10. A semiconductor integrated circuit according to claim 7, wherein the field effect transistor includes a source and the source is the terminal that is not directly connected to the external terminal.

11. A semiconductor integrated circuit according to claim 10, wherein the surge-absorbing element is connected to the source of the field effect transistor.

12. A semiconductor integrated circuit according to claim 7, wherein the field effect transistor includes a drain and the drain is the terminal that is not directly connected to the external terminal.

13. A semiconductor integrated circuit according to claim 12, wherein the surge-absorbing element is not connected to the drain of the field effect transistor.

14. A semiconductor integrated circuit according to claim 1, further comprising additional circuit elements disposed on the substrate including a MESFET, a plurality of diodes, a plurality of resistors, a plurality of capacitors and a plurality of terminals.

15. An electronic apparatus comprising the semiconductor integrated circuit according to claim 1.

16. An electronic apparatus according to claim 15, wherein the electronic apparatus is a mobile phone.

17. An electronic apparatus according to claim 1, wherein the substrate is made of GaAs.
